(19) United States
(12) Patent Application Publication
(10) Pub. No.: US 2003/0102084 A1
(43) Pub. Date: Jun. 5, 2003

(54) Cluster tool for wafer processing having an electron beam exposure module

(76) Inventors: William R. Livesay, San Diego, CA (US); Anthony L. Rubiales, Poway, CA (US); Matthew F. Ross, San Diego, CA (US); David M. Rose, San Diego, CA (US)

Correspondence Address: Roberts & Mercanti, LLP, P.O. Box 484, Princeton, NJ, 08542-0484, US

(21) Appl. No.: 10/342,469

(22) Filed: Jan. 14, 2003

Related U.S. Application Data
(62) Division of application No. 09/272,869, filed on Mar. 19, 1999.

(51) Int. Cl. C23F 1/00; C23C 16/00

(52) U.S. Cl. 156/345.31; 118/719; 118/723 EB

(57) ABSTRACT

A wafer processing cluster tool, having one or more electron beam exposure modules receives wafers from the tool transport mechanism at the internal vacuum pressure of the machine. The loading, unloading, handling and processing of wafers in the machine can occur while other wafers are being treated. The cluster tool has a transport module enclosing an internal volume continuously maintainable under vacuum, a plurality of ports and a wafer transport mechanism for selectively transferring wafers among processing modules. The processing modules perform wafer processing therein under vacuum. At least one semiconductor wafer processing module is an electron beam radiation module. The tool further has a loading module and an unloading module attached to the transport module which are capable of inserting and removing wafers into and out of the transport module from an external environment.

### BACKGROUND OF THE INVENTION

1. Field of the Invention

The present invention relates to a semiconductor wafer processing equipment. More particularly, the invention pertains to the processing of wafers in modular processing systems such as cluster tools. Such tools are useful for sequentially conducting semiconductor treatments in a sealed, controllable environment. Such apparatus is helpful in preventing particle contamination and the throughput of the manufacturing process is thereby significantly increased. Still more particularly, the invention pertains to cluster tools having an electron beam exposure module.

2. Description of the Prior Art

Control of particulate contamination is imperative for cost effective, high-yielding and profitable manufacturing of VLSI circuits. Because circuit designs increasingly require smaller and smaller lines and spaces, it is necessary to exert greater control on the presence of particles. Contamination particles cause incomplete etching in spaces between lines, thus leading to unwanted electrical bridging. In addition to physical defects, contamination particles may cause electrical failure due to induced ionization or trapping centers in gate dielectrics or junctions. The principal sources of particulate contamination are personnel, equipment, and chemicals. Particles given off by personnel are transmitted through the environment and through physical contact or migration onto the wafer surface. In the past, clean rooms were established in which attempts were made to remove particles having geometries of 0.03 micrometer and above through filtering with HEPA and ULPA recirculating air systems and other techniques. There has been a need, however, to improve the processing environment since conventional clean rooms cannot be maintained as particle free as desired. To control contamination particles in clean rooms, filter efficiencies of 99.999% and up to ten complete air exchanges per minute are required to obtain an acceptable level of cleanliness.

As a substitute for clean rooms, certain systems have been designed that will effectively isolate wafers from particles during storage, transport and transfer between processing stations. This is accomplished by ensuring that wafers are isolated from the ambient environment and that particles do not enter the immediate internal wafer environment. Therefore, in the preparation of semiconductor devices, it is now common to employ processing machines such as cluster tools wherein several different and randomly accessible processing stations or modules are connected to a common wafer handling or transport module. Wafers are continuously maintained in an isolated environment at a constant vacuum pressure level, and transferred into and out of an external atmospheric pressure environment through one or more access ports or load-locks. In a typical system, a cassette or carrier with a series of wafers is placed at an interface port of the cluster tool and latches release the port door. A manipulator robot picks up the cassette or individual wafers and directs them to desired processing stations within the equipment. After processing, the reverse operation takes place. Such a wafer processing technique essentially eliminates contaminates since treatment takes place after the wafers are sealed in the internal vacuum environment, and they are not removed prior to completion of processing. The configuration achieves a significant improvement over the conventional handling of open cassettes inside a clean room. In addition, since the vacuum is not broken from step to step, the use of cluster tools increases process productivity. Cluster tools for the processing of semiconductor wafers are well known in the art and are widely commercially available. Such may be exemplified by U.S. Pat. Nos. 5,259,881; 5,280,219; 5,730,801; 5,613,821 and 5,380,682.

While the use of cluster tools has significantly aided semiconductor processing throughput, certain treatments have not been known to be performable in cluster tools. While such steps as coating, heating, cooling, plasma etching, soft etching, ion implantation, and chemical vapor deposition have been done heretofore in cluster tools, electron beam exposure has not been performed in a cluster tool. As a result, when an electron beam exposure curing step is required as part of a process sequence, it has been necessary to perform it either before entry or after removal from a cluster tool arrangement. A problem arises when an electron beam treatment is required as an intermediate step. This has necessitated the removal of a wafer from the tool to perform the electron beam exposure step and reinsertion for continued processing. The present invention solves this problem by providing an electron beam exposure module for a cluster tool. As a result, electron beam exposure can be done directly within a cluster tool, before or after other processing steps, without breaking vacuum or removal from the cluster tool.

### SUMMARY OF THE INVENTION

The invention provides a substrate processing tool comprising:

a) at least one transport module enclosing an internal volume continuously maintainable under vacuum;

b) a plurality of selectively accessible substrate processing modules in vacuum communication with the transport module, each processing module being capable of performing substrate processing therein under vacuum; the transport module having a plurality of ports and a substrate transport mechanism therein for selectively transferring substrates among a plurality of substrate processing modules in vacuum communication therewith through the ports; and wherein at least one substrate processing module is an electron beam radiation module capable of exposing a substrate to electron beam radiation;

c) at least one loading module in communication with the internal volume of the transport module through one of the ports, which is capable of inserting one or more substrates into the transport module from an external environment,

d) at least one unloading module in communication with the internal volume of the transport module through one of the ports, which is capable of removing one or more substrates from the transport module to the external environment.

The invention also provides a process for treating a substrate which comprises

I) providing a substrate processing tool comprising:

a) at least one transport module enclosing an internal volume continuously maintainable under vacuum;

b) a plurality of selectively accessible substrate processing modules in vacuum communication with the transport module, each processing module being capable of performing substrate processing therein under vacuum; the transport module having a plurality of ports and a substrate transport mechanism therein for selectively transferring substrates among a plurality of substrate processing modules in vacuum communication therewith through the ports; and wherein at least one substrate processing module is an electron beam radiation module capable of exposing a substrate to electron beam radiation;

c) at least one loading module in communication with the internal volume of the transport module through one of the ports, which is capable of inserting one or more substrates into the transport module from an external environment,

d) at least one unloading module in communication with the internal volume of the transport module through one of the ports, which is capable of removing one or more substrates from the transport module to the external environment; and

II) exposing a substrate to electron beam radiation in the electron beam radiation module.

The invention also provides an electron beam exposure module which is connectable to a substrate processing cluster tool which comprises a vacuum chamber, means for exposing a substrate to electron beam radiation in the chamber, and an interface for connecting the vacuum chamber in vacuum communication to a substrate processing cluster tool.

### BRIEF DESCRIPTION OF THE DRAWINGS

FIG. 1 shows a top view of a cluster tool arrangement according to the invention.

FIG. 2 shows a side view of a cluster tool arrangement according to the invention.

FIG. 3 shows a schematic diagram of an electron beam exposure tool which forms a part of an electron beam exposure module.

### DETAILED DESCRIPTION OF THE PREFERRED EMBODIMENT

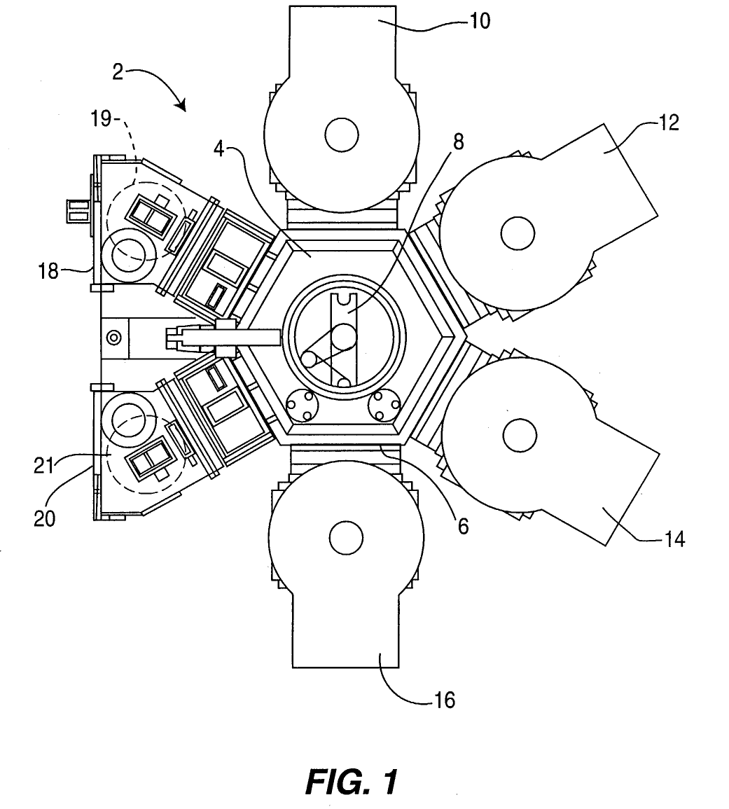

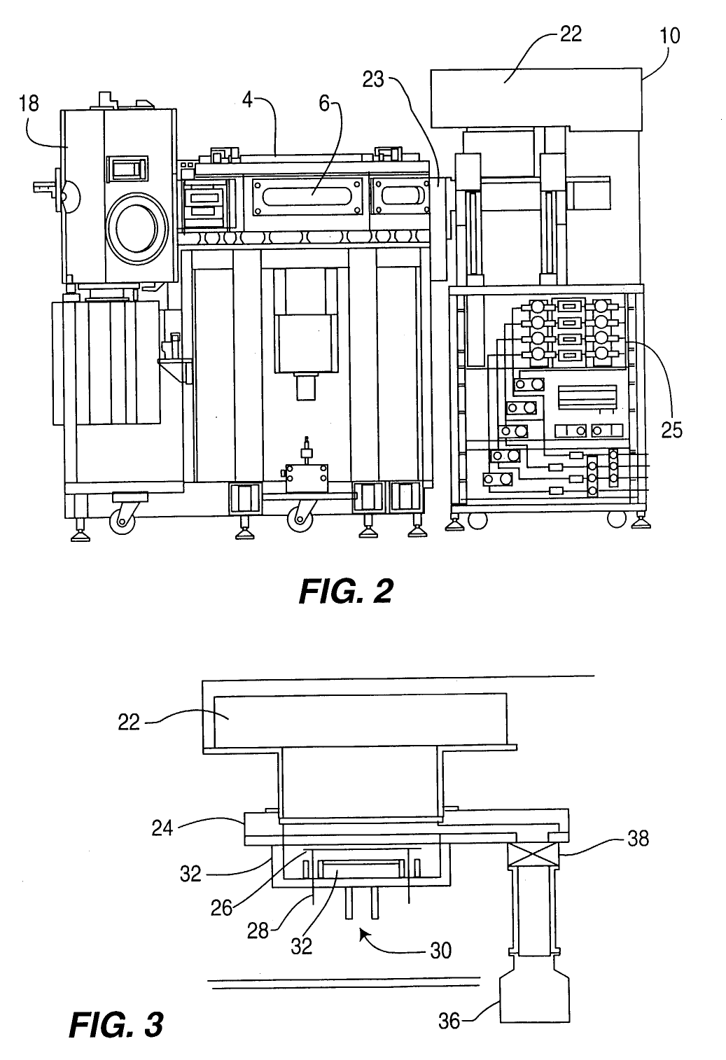

According to the present invention, FIG. 1 shows a top view of a semiconductor wafer processing cluster tool 2 according to the invention. It is shown to comprise a transport module 4 which encloses an internal volume continuously maintainable under a vacuum. The transport module has a plurality of ports 6 which provide ingress and egress to the transport module 4. FIG. 1 shows a configuration wherein the transport module is hexagonal and has a port 6 at each of its six sides. While the embodiment of FIG. 1 shows a hexagonal configuration, it is to be understood that any shape transport module having any number of sides and any number of ports is within the contemplation of the invention. Within the transport module 4 is a wafer transport mechanism 8 for selectively transferring semiconductor wafers among a plurality of semiconductor wafer processing modules 10, 12, 14 and 16 which are attached to the transport module 4 in vacuum communication therewith through the ports 6. Such transport modules are well known in the art and are generally commercially available from The Equipe Division of PRI Automation which is located in Billerica, Mass.

Attached to at least one of the ports 6 is a loading module or loadlock 18 which is in communication with the internal volume of the transport module 4. The loading module is capable of inserting one or more semiconductor wafers into the transport module 4 from the external environment. Also attached to at least one of the ports 6 is an unloading module or loadlock 20 which is in communication with the internal volume of the transport module 4. The loading module is capable of removing one or more semiconductor wafers from the transport module 4 to the external environment. Such loading and unloading modules are well known in the art and are generally commercially available, such as from the Equipe Division of PRI Automation. It is to be understood that although FIG. 1 shows one loading and one unloading module, that a configuration having more than one loading and/or unloading module may be used.

The cluster tools arrangement 2 further has a plurality semiconductor wafer processing modules 10, 12, 14 and 16 which are in vacuum communication with the transport module 4. These modules are accessible by the wafer transport mechanism 8 which can selectively move a wafer from one module to another, or to or from loadlocks 18 and 20 as desired. Each processing module is capable of performing semiconductor wafer processing therein under vacuum, however at least one semiconductor wafer processing module 10 is an electron beam radiation module capable of exposing a semiconductor wafer to electron eam radiation. One or more of modules 12, 14 and 16 may also be electron beam radiation modules or they may be capable of other wafer treatment processes as are well known in the art such as a semiconductor wafer coating module, heating module, cooling module, plasma etching module, ion implantation module, ultraviolet radiation exposure module, chemical mechanical polishing module, sputtering module, annealing module, vapor deposition module, chemical vapor deposition module, plasma enhanced chemical vapor deposition module and physical vapor deposition module. Such additional modules are well known in the art and are generally commercially available from such manufacturers as the Equipe Division of PRI Automation, Applied Materials, LAM Research, Materials Research Corporation and Novellus.

When processing wafers in the cluster tool of the invention, it is often desired to heat the wafers prior to performing one or more of the foregoing treatments. In order to increase the throughput of the tool, it is advantageous to include preheating means, such as a hotplate 19 in the loading module 18. Heating may be done from a temperature of from about 25° C. to about 500° C. Likewise, prior to returning, the wafers to atmospheric conditions, it is advantageous to include cooling means, such as a cooling platen 21 in the unloading module 20. Cooling may reduce the temperature of the wafer from maximum temperature to which it has been heated in the cluster tool down to about room temperature, i.e. about 20° C., or lower. If the wafers are returned to atmospheric conditions prior to sufficient cooling, they tend to be subjected to unwanted oxidation.

The cluster tool arrangement according to the invention comprises an electron beam exposure module 10 connected to the transport module 4 of cluster tool 2 via an interface 23. FIG. 3 shows a schematic representation of the electron beam exposure tool which forms a part of an electron beam exposure module. It comprises an electron source 22 which projects electrons through a chamber 24 onto a wafer 26 which is placed on lift pins 28. Lift pins 28 are positioned by a suitable pneumatic lift 30. Electron beam exposure is preferably done in a thermal processing chamber 32 wherein the wafers are heated buy means of quartz lamps 32 which heats the wafers by means of quartz lamps 34. The chamber 24 is maintained at a desired vacuum via a pump 36 which is controlled by a valve 38.

Preferably, the electron beam exposure tool which is used which provides an large area electron source 27. Suitable electron beam tools are commercially available from Electron Vision, a unit of AlliedSignal Inc., under the trade name “ElectronCure™”. The principles of operation and performance characteristics of such device are described in U.S. Pat. No. 5,001,178, the disclosure of which is expressly incorporated herein by reference. The electron beam radiation module comprises a uniform, large-area, overall electron beam exposure source which covers an exposure area of from about 4 square inches to about 256 square inches. The temperature of the wafer during electron beam exposure preferably ranges from about 20° C. to about 450° C., more preferably from about 150° C. to about 400° C. The electron beam energy is preferably from about 1 to about 30 KeV, and more preferably from about 3 to about 10 KeV. The dose of electrons is preferably from about 1 to about 50,000 μC/cm² and more preferably from about 3,000 to about 20,000 μC/cm². The gas ambient in the electron beam tool can be any of the following gases: nitrogen, oxygen, hydrogen, argon, helium, ammonia, silane, xenon or any combination of these gases. Gases are supplied in the electron beam module via gas lines and regulators 25. The electron beam current is preferably from about 1 to about 150 mA, and more preferably from about 5 to about 50 mA.

While the present invention has been particularly shown and described with reference to preferred embodiments, it will be readily appreciated by those of ordinary skill in the art that various changes and modifications may be made without departing from the spirit and scope of the invention. It is intended that the claims be to interpreted to cover the disclosed embodiment, those alternatives which have been discussed above and all equivalents thereto.

What is claimed is:

1. A substrate processing tool comprising:
a) at least one transport module enclosing an internal volume continuously maintainable under vacuum;
b) a plurality of selectively accessible substrate processing modules in vacuum communication with the transport module, each processing module being capable of performing substrate processing therein under vacuum; the transport module having a plurality of ports and a substrate transport mechanism therein for selectively transferring substrates among a plurality of substrate processing modules in vacuum communication therewith through the ports; and wherein at least one substrate processing module is an electron beam radiation module capable of exposing a substrate to electron beam radiation;
c) at least one loading module in communication with the internal volume of the transport module through one of the ports, which is capable of inserting one or more substrates into the transport module from an external environment,
d) at least one unloading module in communication with the internal volume of the transport module through one of the ports, which is capable of removing one or more substrates from the transport module to the external environment.

2. The tool of claim 1 comprising a plurality of electron beam radiation modules capable of exposing a substrate to electron beam radiation.

3. The tool of claim 1 further comprising at least one additional loading module in communication with the internal volume of the transport module through one of the ports, which is capable of inserting one or more substrates into the transport module from an external environment.

4. The tool of claim 1 further comprising at least one additional unloading module in communication with the internal volume of the transport module through one of the ports, which is capable of removing one or more substrates from the transport module to the external environment.

5. The tool of claim 1 further comprising at least one additional loading module in communication with the internal volume of the transport module through one of the ports, which is capable of inserting one or more substrates into the transport module from an external environment; and at least one additional unloading module in communication with the internal volume of the transport module through one of the ports, which is capable of removing one or more substrates from the transport module to the external environment.

6. The tool of claim 1 wherein the electron beam radiation module comprises a uniform, large-area, overall electron beam exposure source.

7. The tool of claim 1 wherein the electron beam radiation module comprises a uniform large-area electron beam source which covers an exposure area of from about 4 square inches to about 256 square inches.

8. The tool of claim 1 wherein the electron beam exposure source generates an electron beam energy level ranging from about 1 to about 30 KeV.

9. The tool of claim 1 wherein the electron beam radiation exposure source generates an electron dose ranging from about 1 to about 50,000 μC/cm².

10. The tool of claim 1 wherein the electron beam exposure source generates an electron beam current of from about 1 to about 150 mA.

11. The tool of claim 1 wherein the electron beam radiation module comprises heating means.

12. The tool of claim 1 wherein the electron beam radiation module contains a gas selected from the group consisting of nitrogen, oxygen, hydrogen, argon, xenon, helium, ammonia, silane and mixtures thereof.

13. The tool of claim 1 wherein the electron beam radiation module comprises heating means capable of maintaining its internal temperature in the range of from about 20° C. to about 450° C.

14. The tool of claim 1 wherein the vacuum is in the range of from about 10⁻⁵ to about 10² torr.

15. The tool of claim 1 comprising one or more modules selected from the group consisting of a substrate coating module, heating module, cooling module, plasma etching module, ion implantation module, ultraviolet radiation exposure module, chemical mechanical polishing module, sputtering module, annealing module, vapor deposition module, chemical vapor deposition module, plasma enhanced chemical vapor deposition module and physical vapor deposition module.

16. The tool of claim 1 wherein the loading module comprises heating means therein.

17. The tool of claim 1 wherein the unloading module comprises cooling means therein.

18. A process for treating a substrate which comprises
I) providing a substrate processing tool comprising:
a) at least one transport module enclosing an internal volume continuously maintainable under vacuum;
b) a plurality of selectively accessible substrate processing modules in vacuum communication with the transport module, each processing module being capable of performing substrate processing therein under vacuum; the transport module having a plurality of ports and a substrate transport mechanism therein for selectively transferring substrates among a plurality of substrate processing modules in vacuum communication therewith through the ports; and wherein at least one substrate processing module is an electron beam radiation module capable of exposing a substrate to electron beam radiation;
c) at least one loading module in communication with the internal volume of the transport module through one of the ports, which is capable of inserting one or more substrates into the transport module from an external environment,
d) at least one unloading module in communication with the internal volume of the transport module through one of the ports, which is capable of removing one or more substrates from the transport module to the external environment; and
II) exposing a substrate to electron beam radiation in the electron beam radiation module.

19. The process of claim 18 wherein the electron beam radiation exposing is conducted with a uniform, large-area, overall electron beam exposure source.

20. The process of claim 18 wherein the electron beam radiation exposing is conducted with a uniform large-area electron beam source which covers an exposure area of from about 4 square inches to about 256 square inches.

21. The process of claim 18 wherein the electron beam exposure source generates an electron beam energy level ranging from about 1 to about 30 KeV.

22. The process of claim 18 wherein the electron beam radiation exposure source generates an electron dose ranging from about 1 to about 50,000 μC/cm².

23. The process of claim 18 wherein the electron beam exposure source generates an electron beam current of from about 1 to about 150 mA.

24. The process of claim 18 wherein the electron beam radiation exposure is conducted while heating the substrate.

25. The process of claim 18 wherein the electron beam radiation exposure is conducted in a gas selected from the group consisting of nitrogen, oxygen, hydrogen, argon, xenon, helium, ammonia, silane and mixtures thereof.

26. The process of claim 18 wherein the electron beam radiation exposure is conducted while heating at a temperature in the range of from about 20° C. to about 450° C.

27. The process of claim 18 wherein the vacuum maintained in the range of from about 10⁻⁵ to about 10² torr.

28. The process of claim 18 wherein the substrate is subjected to one or more additional treatments within the tool selected from the group consisting of coating, heating, cooling, plasma etching, ion implantation, ultraviolet radiation exposure, chemical mechanical polishing, sputtering, annealing, vapor deposition, chemical vapor deposition, plasma enhanced chemical vapor deposition and physical vapor deposition.

29. The process of claim 18 wherein the substrate is heated in the loading module.

30. The process of claim 18 wherein the substrate is cooled in the unloading module.

31. The process of claim 18 wherein the substrate comprises a semiconductor wafer.

32. An electron beam exposure module which is connectable to a substrate processing cluster tool which comprises a vacuum chamber, means for exposing a substrate to electron beam radiation in the chamber, and an interface for connecting the vacuum chamber in vacuum communication to a substrate processing cluster tool.
